(19) United States
(12) Patent Application Publication
(10) Pub. No.: US 2015/0262939 A1
(43) Pub. Date: Sep. 17, 2015

(54) Semiconductor Device and Method Of Manufacturing the Same

(71) Applicant: Kabushiki Kaisha Toshiba, Tokyo (JP)

(72) Inventor: Atsuko SAKATA, Yokkaichi (JP)

(21) Appl. No.: 14/643,440

(22) Filed: Mar. 10, 2015

(30) Foreign Application Priority Data
Mar. 14, 2014 (JP) 2014-052124

(51) Int. Cl. H01L 23/532; H01L 21/768; H01L 23/522

(52) U.S. Cl. CPC H01L 23/53266; H01L 23/5226; H01L 21/76877; H01L 21/76847

(57) ABSTRACT

A semiconductor device is provided with an insulating film including a recess and a wiring structure including at least either of tungsten and molybdenum. The wiring structure includes a wiring portion provided along a surface portion of the insulating film and provided with a first layer and a second layer. A concentration of at least either of fluorine and chlorine in the second layer is greater than a concentration of either of fluorine and chlorine in the first layer. A plug is filled in the recess of the insulating film and is connected to the wiring portion. The plug is continuous with and structurally integral with the second layer of the wiring portion.

### CROSS-REFERENCE TO RELATED APPLICATION(S)

This application is based upon and claims the benefit of priority from Japanese Patent Application No. 2014-052124, filed on, Mar. 14, 2014 the entire contents of which are incorporated herein by reference.

### FIELD

Embodiments disclosed herein generally relate to a semiconductor device and a method of manufacturing the same.

### BACKGROUND

In a wiring structure of a semiconductor device, low resistance metals such as copper (Cu) is typically used as a plug for providing connection between wires and layers. In advanced semiconductor devices, wirings and plugs are expected to undergo further miniaturization. Thus, use of metal materials such as Cu, in which the mean free path of electrons is long, will cause performance degradation such as increased resistance. One solution may be filling a contact hole for example with tungsten (W), in which the mean free path of electrons is short, using CVD (Chemical Vapor Deposition). In such approach, a hole is formed through an insulating film such as a silicon oxide film (SiO₂) for accessing an electrode for example located in the underlying layer. Then, an adhesion layer comprising a stack of titanium (Ti) film and titanium nitride (TiN) film for example is formed along the inner side surface of the hole. Thereafter, the hole is filled with W for example by CVD using tungsten hexafluoride (WF₆) or tungsten hexachloride (WCl₆).

In the above described process in which the hole is filled with W using CVD, W layer is deposited above the insulating film as well. It is thus, possible to form a wiring portion above the plug continuing with the plug by, for example, patterning W layer deposited above the insulating film by etching or the like. A CVD process carried out using WF₆ source or WCl₆ source achieves high coverage and thus, is effective in filling the hole. However, the resulting layers contain relatively high concentration of F or Cl impurity and thus, the diffusion of such impurities, especially F, may be a concern.

### BRIEF DESCRIPTION OF THE DRAWINGS

FIGS. 1A, 1B, and 1C pertain to a first embodiment and are vertical cross sectional views each illustrating an example of one phase of a manufacturing process flow of a semiconductor device.

FIG. 2 pertains to the first embodiment and is a vertical cross-sectional view illustrating one example of a cross sectional structure of main portions of the semiconductor device.

FIG. 3 pertains to a second embodiment and is a vertical cross-sectional view illustrating one example of a cross sectional structure of main portions of a semiconductor device.

FIG. 4 pertains to a third embodiment and is a vertical cross-sectional view illustrating one example of a cross sectional structure of main portions of a semiconductor device.

FIGS. 5A, 5B, and 5C pertain to a fourth embodiment and are vertical cross-sectional views each illustrating an example of one phase of a manufacturing process flow of a semiconductor device.

FIG. 6 pertains to the fourth embodiment and is a vertical cross-sectional view illustrating one example of a cross sectional structure of main portions of the semiconductor device.

FIGS. 7A and 7B pertain to a fifth embodiment and are vertical cross sectional views each illustrating an example of one phase of a manufacturing process flow of a semiconductor device.

### DESCRIPTION

In one embodiment, a semiconductor device is provided with an insulating film including a recess; and a wiring structure including at least either of tungsten and molybdenum, the wiring structure including a wiring portion provided along a surface portion of the insulating film and provided with a first layer and a second layer, a concentration of at least either of fluorine and chlorine in the second layer being greater than a concentration of either of fluorine and chlorine in the first layer, and a plug filling the recess of the insulating film and being connected to the wiring portion, the plug being continuous with and structurally integral with the second layer of the wiring portion.

In one embodiment, a semiconductor device is provided with an insulating film including a recess; and an embedded wiring portion including at least either of tungsten and molybdenum, the embedded wiring portion provided with a first layer filled in the recess of the insulating film so as to cover an inner surface of the recess, and a second layer filing an inner side of the first layer in the recess, a concentration of at least either of fluorine and chlorine in the second layer being greater than a concentration of either of fluorine and chlorine in the first layer.

In one embodiment, a method of manufacturing a semiconductor device provided with an insulating film having a recess and a wiring structure containing at least either of tungsten and molybdenum and being provided along the insulating film is disclosed. The method includes forming a wiring portion by depositing a first layer by chemical vapor deposition or atomic layer deposition using a first source containing substantially no fluorine, and depositing a second layer by chemical vapor deposition or atomic layer deposition using a second source containing at least either of fluorine or chlorine and being different from the first source, the first layer and the second layer being stacked along a surface portion of the insulating film.

Embodiments are described herein with reference to the accompanying drawings. The drawings are schematic and are not necessarily consistent with the actual relation between thickness and planar dimensions as well as the ratio of thicknesses between different layers, etc. Further, directional terms such as up, down, left, and right are used in a relative context with an assumption that the surface, on which circuitry is formed, of the later described semiconductor substrate faces up and thus, do not necessarily correspond to the directions based on gravitational acceleration.

### First Embodiment

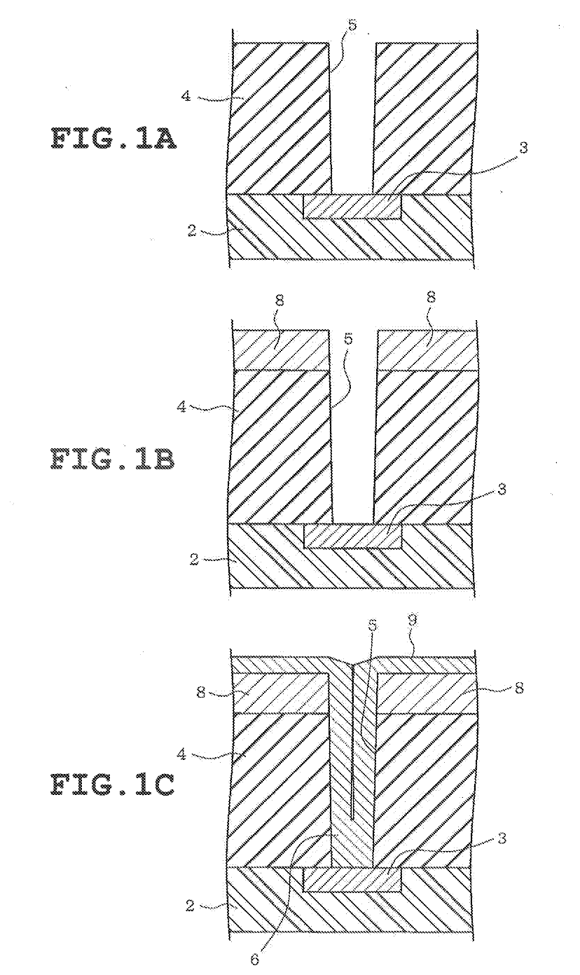

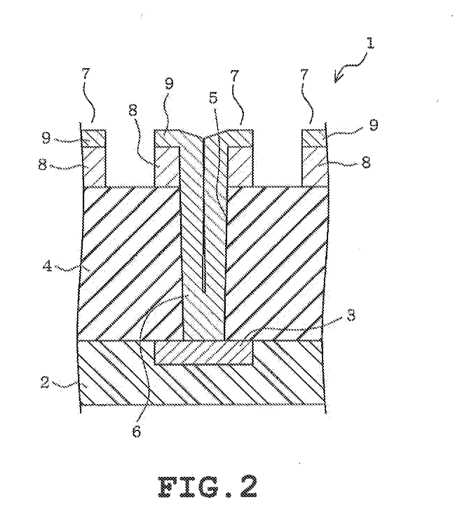

A description is given hereinafter on a semiconductor device of the first embodiment with reference to FIGS. 1A to 1C and FIG. 2. FIG. 2 schematically illustrates one example a cross section of the main portions of semiconductor device 1. Insulating film 4 comprising a silicon oxide film (SiO₂) for example is disposed above semiconductor substrate 2 having semiconductor elements not shown formed therein and thereabove. More specifically, insulating film 4 is disposed above electrode 3, also referred to as a lower wiring, provided above semiconductor substrate 2. Hole 5 serving as a recess is formed through interlayer insulating film 4 so as to be located above electrode 3. One would appreciate that there may be multiplicity of electrodes 3 and holes 5 though only one of each are illustrated.

Hole 5 is filled with plug 6 which connects electrode 3 with wiring portion 7 located in a higher layer. Metal such as tungsten (W) may be used as plug 6. Wiring portion 7 is formed above insulating film 4. In the first embodiment, wiring portion 7 is structured as a double layer of first layer 8 disposed above insulating film 4 and second layer 9 disposed above first layer 8. In this example, first layer 8 and second layer 9 both comprise tungsten (W). Second layer 9 is structurally integral or is continuous with plug 6.

As will be mentioned in the later described manufacturing process flow, first layer 8 and second layer 9 are formed by chemical vapor deposition (CVD). Among the two, first layer 8 is formed by CVD using tungsten carbonyl (W(CO)₆) as a source which does not contain fluorine (F) nor chlorine (Cl). In contrast, second layer 9 is formed by CVD using hexatungsten fluoride (WF₆) or hexatungsten chloride (WCl₆) as a source which contain fluorine (F) or chlorine (Cl). As described earlier, second layer 9 and plug 6 are structurally integral and are thus, formed simultaneously. As a result, first layer 8 contains relatively low concentration of F or Cl impurity and relatively high concentration of carbon (C) or oxygen (O). Second layer 9 contains relatively high concentration of F or Cl impurity.

Next, a description is given hereinafter on a method of manufacturing semiconductor device 1 of the first embodiment with reference to FIGS. 1A, 1B, and 1C. FIGS. 1A, 1B, and 1C illustrate one example of a manufacturing process flow of semiconductor device 1 structured as described above. Referring first to FIG. 1A, insulating film 4 is formed in a predetermined thickness above semiconductor substrate 2. Hole 5 extending to the underlying electrode 3 is formed through insulating film 4 by etching or the like.

Referring now to FIG. 1B, a first CVD process is executed for forming first layer 8. The first CVD process begins with placing semiconductor 2 with hole 5 into a CVD chamber not shown. Then, deposition takes place using tungsten carbonyl (W(CO)₆) by controlling the pressure and temperature inside the chamber to predetermined conditions. As a result, W is deposited above insulating film 4 in a predetermined thickness of 50 nm for example.

A CVD carried out with a carbonyl source tend to provide poor coverage compared to a CVD carried out with a fluoride source or chloride source. Thus, there is not much deposit of W near the opening of hole 5. As a result, first layer 8 is formed without closing the opening of hole 5 while being in good adhesion with SiO₂ at the surface portion of insulating film 4. It is thus, possible to form first layer 8 directly on oxide film (SiO₂) without providing a barrier metal. Further, first layer 8 is not easily influenced by the underlying structure and is capable of producing tungsten having large grain diameters. The gases inside the chamber are purged after the formation of first layer 8. The tungsten carbonyl (W(CO)₆) source gas may be replaced by other organic compound sources that do not substantially contain F or Cl.

Referring now to FIG. 1C, second CVD process is carried out for forming plug 6 and second layer 9. Because a barrier film is not formed in the first embodiment, a thin silicon (Si) film not shown is formed as an underlay along the inner surface of hole 5 and along the surface of first layer 8 prior to the formation of plug 6 and second layer 9, in order to facilitate the formation of the initial nucleus layer of W. Though not illustrated, the process for forming the Si film begins by specifying the pressure inside the chamber to range from 5000 Pa to 15000 Pa, whereafter B₂H₆ gas is introduced into the chamber at a flow rate of 1000 sccm. Then, without purging, SiH₄ gas and H₂ gas are introduced into the chamber at flow rates of 700 sccm and 500 sccm, respectively.

As a result, silicon (Si) film being approximately 0.1 to nm thick for example is formed conformally along the inner surface of hole 5 and along the surface of first layer 8. The gases inside the chamber are purged after the formation of the Si film. This is followed by a deposition using WF₆ as a source gas in which a reduction reaction takes place using the Si film serving as an underlay. This causes deposition of W filling hole 5 and further overlying first layer 8.

Though not described in detail, the formation of second layer 9 may be carried out in two phases in which the formation of initial nucleus layer is followed by W deposition. The formation of the initial nucleus layer repeats the cycle of for example: introducing WF₆ gas into the chamber by specifying the pressure inside the chamber at a predetermined pressure and a predetermined temperature ranging approximately from 200 degrees Celsius to 500 degrees Celsius for example; purging; introducing SiH4 gas serving as a reduction gas; and purging. As a result, the Si film reacts with WF₆ gas and forms a dense initial nucleus layer of W along the inner surface of hole 5 and along the surface of first layer 8. In this example, the grain diameter of W forming the initial nucleus layer is less than 20 nm. Thus, the initial nucleus layer exhibits outstanding gap fill capability and the thin Si film formed as an underlay may serve as a liner. It is thus, possible to form a layer possessing high coverage along the inner surface of hole 5. Such initially formed layer contains relatively low F content. Thus, depending upon the size of hole 5 it is possible to fill most of hole 5 with initial nucleus layer. Thus, it is possible to reduce the thickness of W deposited using WF₆ gas and H₂ gas in the subsequent phase, and thereby reduce the overall F concentration in second layer 9. It is thus, possible to improve the corrosion resistance of wiring structures.

In forming the initial nucleus layer, WF₆ gas and SiH₄ gas may be introduced into the chamber simultaneously, instead of repeating the cycle of independent introduction of WF₆ and SiH₄ gases and purging. These tasks may be arranged depending upon the pattern of hole 5 to be filled. Further in this example, B₂H₆ gas may be used as the reduction gas instead of SiH₄ gas.

In the subsequent W deposition phase, W is deposited above the initial nucleus layer by introducing WF₆ gas and H₂ gas into the chamber. Hole 5 is thus, filled with W to form plug 6. The formation of plug 6 also forms second layer 9 extending continuously from plug 6 so as to be stacked above first layer 8. Alternatively, when hole 5 is small, the filling of hole 5 and formation of second layer 9 may be carried out by the formation of the initial nucleus layer, using SiH₄ gas or B₂H₆ gas as the reduction gas, in which case W deposition using WF₆ gas and H₂ gas may be omitted. In such case, the upper surface of second layer 9 is formed of the initial nucleus layer having a small grain diameter. Thus, second layer 9 exhibits a surface with high planarity, which works advantageously when forming wiring patterns by lithography.

Next, the upper surface of second layer 9 is planarized as required using chemical mechanical polishing (CMP) or etch back. Then, as illustrated in FIG. 2, unwanted portions of the two metal layers 8 and 9 disposed above insulating film 4 are removed by etching or the like to pattern wiring portions 7. The resulting wiring portions 7 are configured as a stack structure or a double layered structure of first layer 8 and second layer 9 both comprising W.

In semiconductor device 1 of the first embodiment structured as described above, hole 5 is filled well with plug 6 exhibiting high coverage formed by CVD using a fluorine (F)-containing source such as WF₆ or a chlorine (Cl)-containing source such as WCl₆. Plug 6 contains relatively high concentration of F or Cl impurity. Wiring portion 7 connected to plug 6 is formed of a stack of first layer 8 and second layer 9. Among the two, first layer 8 is formed by CVD using a source such as tungsten carbonyl (W(CO)₆) which does not contain fluorine (F) nor chlorine (Cl). Thus, first layer 8 contains relatively low concentration of F impurity and relatively high concentration of C or O.

Thus, the first embodiment achieves outstanding advantages of providing a wiring structure having plugs 6 and wiring portions 7 in which holes 5 are filled well and resistance of wiring portions 7 are reduced. Because second layer 9 contains F or Cl, corrosion originating from interactions with ambient moisture, etc. may be encountered more frequently as compared to first layer 8. However, this may be viewed as second layer 9 serving as a sacrificial layer in which interactions with water is concentrated in second layer 9 containing F or Cl. As a result, the influence of water is reduced in first layer 8 not containing or at least containing relatively less amount of F or Cl to achieve high corrosion resistance. It is thus, possible to obtain a durable wiring structure capable of maintaining a low resistance level over a long period of time.

The profile of impurity concentrations is substantially maintained though some thermal diffusion of impurities may occur between the layers as the result of subsequent thermal treatments. Further, because a thin Si film and an initial nucleus layer having a relatively low concentration of F or Cl is formed after first layer 8, diffusion of F or Cl into first layer 8 is inhibited. It is thus, possible to protect first layer 8 from corrosion originating from second layer 9 side. In this example, the initial nucleus layer, formed between first layer 8 containing no or relatively less F or Cl and the upper side film containing relatively large amount of F or Cl which is formed using WF₆ gas and H₂ gas, has a small crystal grain diameter. Further, Si contained in second layer 9 is used to getter F or Cl and serves as a protective layer for first layer 8.

In the first embodiment, first layer 8 is formed after hole is formed through insulating film 4. Alternatively, first layer 8 may be formed above the surface of insulating film 4 by carrying out the first CVD process. Hole 5, serving as a recess, may be formed through first layer 8 and insulating film 4 to obtained the structure illustrated in FIG. 1B. Then, second layer 9 is formed by carrying out the second CVD process as illustrated in FIG. 1C as was the case in the first embodiment, whereafter a patterning process is carried out as illustrated in FIG. 2 to obtain semiconductor device 1.

### Second Embodiment

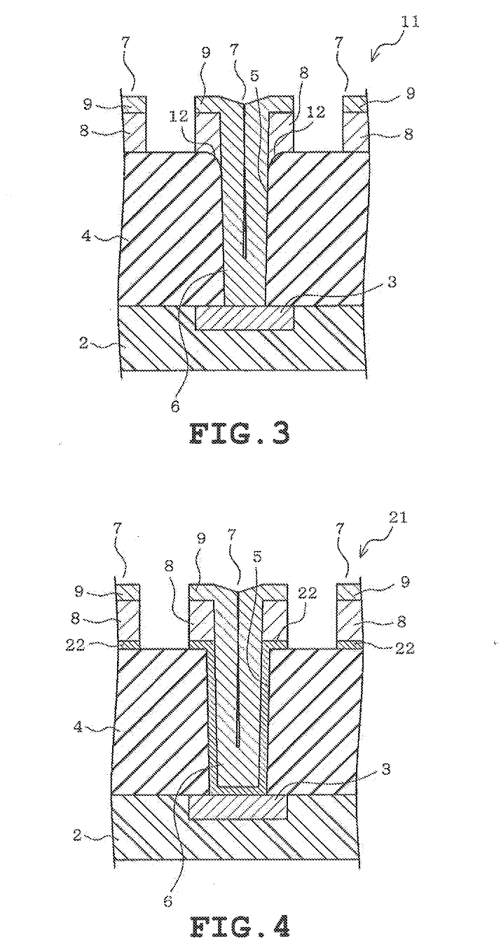

FIG. 3 schematically illustrates one example of a cross-sectional structure of semiconductor device 11 of a second embodiment. Semiconductor device 11 of the second embodiment differs from semiconductor device 1 of the first embodiment in that rounded portion 12 is provided on insulating film 4 located at the mouth, i.e. the opening portion of hole 5. Rounded portion 12 may be provided for example by chemical dry etching.

The first CVD process for providing first layer 8, using a source such as W(CO)₆ which does not contain F or Cl, is carried out in the second embodiment as well. The first CVD process is followed by the second CVD process for providing second layer 9 using a source such as WF₆ or WCl₆ which contains F or Cl. In the first CVD process, the deposition of first layer 8 may narrow the opening portion of hole 5 located at the upper end portion of hole 5. However, because rounded portion 12 is provided at the opening portion of hole 5 prior to the first CVD process, it is possible to prevent the opening portion of hole 5 from becoming excessively narrowed. As a result, it is possible to keep hole 5 opened and enable good filling of hole 5 in the subsequent second CVD process.

### Third Embodiment

FIG. 4 schematically illustrates one example of a cross-sectional structure of semiconductor device 21 of a third embodiment. Semiconductor device 21 of the third embodiment differs from semiconductor device 1 of the first embodiment in that adhesion layer 22 is formed along the surface of insulating film 4 and along the inner surface of hole 5. Adhesion layer 22 comprises a titanium nitride (TiN) film for example and is formed after hole is provided through insulating film 4. Adhesion layer 22 may be formed by physical vapor deposition (PVD), CVD, atomic layer deposition (ALD), or the like. After forming adhesion layer 22, the first CVD process followed by the second CVD process is carried out as was the case in the first embodiment. Adhesion layer 22, disposed along insulating film 4, is removed in the portions which do not serve as wiring portions 7 in the subsequent patterning process.

In the third embodiment described above, it is possible to improve the adhesion of first layer 8 and insulating film 4 as well as the adhesion of plug 6 in hole 5 more effectively by providing adhesion layer 22. Adhesion layer 22 also serves as a barrier metal for inhibiting impurity diffusion. TiN film used as adhesion layer 22 may be replaced by a stack of titanium (Ti) film and titanium nitride (TiN) film. Further, adhesion layer 22 may be formed only near the opening portion of hole 5 instead of being formed along the entire extent of the upper surface of insulating film 4 and the inner surface of hole 5. Further, adhesion layer 22 may be provided after providing rounded portion 12 at the opening portion of hole 5 as was the case in the above described second embodiment.

### Fourth Embodiment

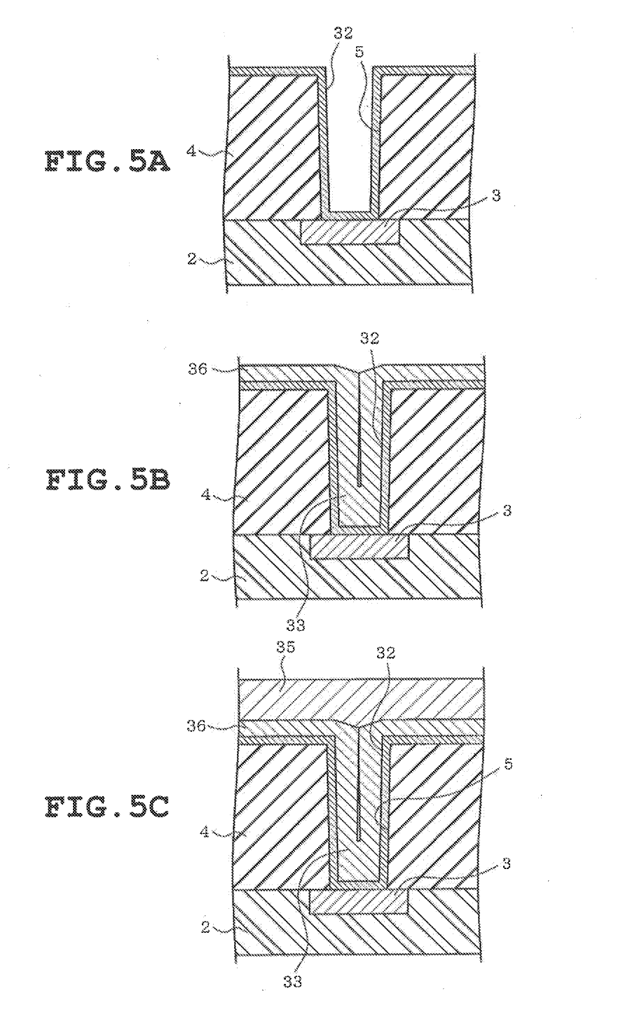

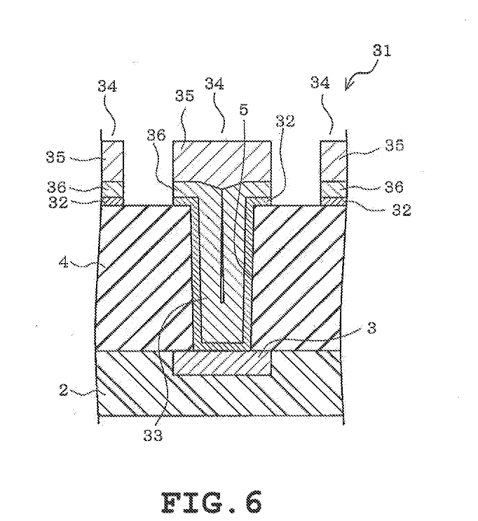

Next, a description will be given on a fourth embodiment with reference to FIG. 5A to 5C and FIG. 6. Elements that are identical to those of the first embodiment are identified with identical reference symbols and are not re-described in detail. The differences from the first embodiment are discussed hereinafter. FIG. 6 schematically illustrates one example of a cross-sectional structure of semiconductor device 31 of the fourth embodiment. The fourth embodiment also has insulating film 4 formed above semiconductor substrate 2. Insulating film 4 may be formed of a silicon oxide film (SiO₂) for example. More specifically, insulating film 4 is disposed above electrode 3 provided above semiconductor substrate 2 and hole 5 is formed through interlayer insulating film 4 so as to be located above electrode 3.

Adhesion layer 32 comprising a TiN film or a stack of Ti film and TiN film is formed along the surface of insulating film 4 where the wiring portions are formed and along the inner surface of hole 5. Hole 5 is filled with plug 33 which connects electrode 3 with wiring portion 34 located in a higher layer. Metal such as tungsten (W) may be used as plug 33. Wiring portion 34 is formed above insulating film 4. In the fourth embodiment, wiring portion 34 is structured as a double layer of second layer 36, disposed above insulating film 4 or more specifically above adhesion layer 32, and first layer 35 disposed above second layer 36. In this example, second layer 36 and first layer 35 both comprise tungsten (W). Second layer 36 is structurally integral or is continuous with plug 33.

Second layer 36 and first layer 35 are formed by chemical vapor deposition (CVD). Among the two, second layer 36 is formed by CVD using WF₆ or WCl₆ as a source which contains F or Cl. As described earlier, second layer 36 and plug 33 are structurally integral and are thus, formed simultaneously. In contrast, first layer 35 is formed by CVD using tungsten carbonyl (W(CO)₆) as a source which does not contain F nor Cl. As a result, first layer contains relatively low concentration of F or Cl impurity and relatively high concentration of carbon (C) or oxygen (O). Second layer 36 contains relatively high concentration of F or Cl impurity.

FIGS. 5A to 5C illustrate one example of a manufacturing process flow of above described semiconductor device 31 subsequent to the formation of hole 5. In the fourth embodiment, adhesion layer 32 comprising a TiN film for example is formed along the surface of insulating film 4 and along the inner surface of hole 5 as illustrated in FIG. 5A. Adhesion layer 32 may be formed by PVD, CVD, ALD, or the like. Then, CVD processes using two different types of sources described in the first embodiment are carried out. The fourth embodiment differs from the first embodiment in that the sequence of the CVD processes is reversed. A stack of Ti film and TiN film may be provided at the bottom portion of hole 5 for forming a contact. Alternatively, a thin Si film serving as an underlay may be formed as was the case in the first embodiment.

Referring first to FIG. 5B, second layer 36 comprising W is formed along the surface portion of adhesion layer 32. In this example, second layer 36 is formed by CVD using WF₆ or WCl₆ as a source which contains F or Cl and which achieves good filling of hole 5. Plug 33 continuing with second layer 36 is formed in hole 5. In this example, formation of second layer 36 is carried out using SiH₄ gas or B₂H₆ gas as the reduction gas which is capable of reducing the damages to the underlying layer originating from F and forms an initial nucleus layer of W having a grain diameter less than 20 nm. Alternatively, when hole 5 is small, hole 5 is substantially filled with the initial nucleus layer and a thin W film is formed above the surface portion of insulating film 4. Such initially formed layer contains relatively low amount of F content.

Then, though not illustrated, a process for forming an amorphous layer above the initial nucleus layer (second layer 36) is carried out which is one example of an approach to isolate the initial nucleus layer and prevent the orientation or the grain diameter of the initial nucleus layer from affecting the films formed thereabove. Amorphous layers formed by gases used in the initial nucleus layer may be effective in providing such isolation. Examples of such amorphous layers may be an amorphous Si layer formed by SiH₄ gas or an amorphous B layer formed by B₂H₆. In case it is possible to fill hole 5 with the initial nucleus layer, it is not required to form the above described amorphous layer. In case the initial nucleus layer is not sufficient for filling hole 5, a film may be formed using WF₆ and H₂ gas to fill remaining portion of hole 5. In such case, an amorphous layer similar to the one already formed may be formed again on top of the fill.

Then, as illustrated in FIG. 5C, first layer 35 is formed along second layer 36, or the amorphous layer if formed, by CVD using a source which does not contain F nor Cl, such as tungsten carbonyl (W(CO)₆). The tungsten carbonyl (W(CO)₆) source gas may be replaced by other organic compound sources that substantially contain no F nor Cl. Especially when forming first layer 35 along the surface portion of second layer 36, resistance may be lowered by removing impurities by NH₃ or H₂ plasma. First layer 35 can be rendered less affected by the underlying second layer 36 when isolated by the amorphous layer. First layer 35 can thus, be formed with large grain diameters ranging from 10 to 200 nm for example.

Then, a patterning process is carried out to pattern wiring portions 34 by removing unwanted portions of the two layers of metal 36 and 35 disposed above insulating film 4 by etching or the like as illustrated in FIG. 6. The resulting wiring portions 34 are configured as a stack structure or a double layered structure of second layer 36 and first layer 35 both comprising W. Because little F or Cl diffusion will result from a thermal process in the above described structure, it is possible to form wiring portions 34 having low resistance by subjecting wiring portions 34 to sufficient thermal treatment.

In semiconductor device 31 structured as described above, it is possible to achieve good filling of hole 5 by carrying out CVD using a source which contains F or Cl such as WF₆ or WCl₆ and thereby forming plug 33 with high coverage. Plug 33 filling hole can be formed as a film containing relatively small amount of F as described earlier. Wiring portion 34 connected to plug 33 forms a stack with second layer 36 and first layer 35. Among them, first layer 35, being formed by CVD using a source not containing F nor Cl such as (W(CO)₆) contains relatively low concentration of F impurity and relatively high concentration of carbon (C) or oxygen (O).

Thus, the fourth embodiment achieves outstanding advantages of providing a wiring structure having plugs 33 and wiring portions 34 in which holes 5 are well filled and resistance of wiring portions 34 are reduced.

### Fifth Embodiment

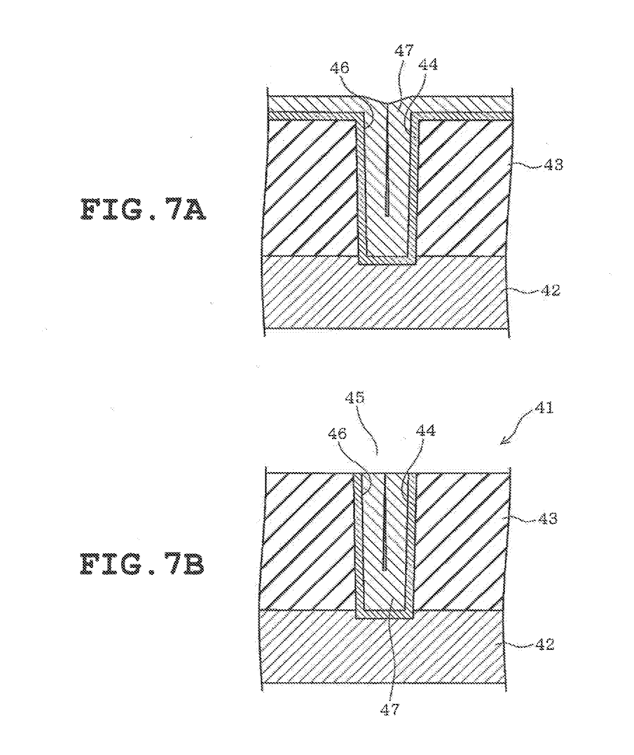

Next, a description will be given on a fifth embodiment with reference to FIGS. 7A to 7B. Elements that are identical to those of the first embodiment are identified with identical reference symbols and are not re-described in detail. The differences from the first embodiment are discussed hereinafter. FIG. 7B schematically illustrates one example of a cross-sectional structure of semiconductor device 41 of a fifth embodiment. Semiconductor device 41 also has insulating film 43 disposed in contact with an element portion such as a semiconductor region of a transistor. A silicon oxide film (SiO₂) may be used for example as insulating film 43.

Trench 44 serving as a recess is formed into insulating film 43 so as to expose element portion 42. Trench 44 extends in the front and rear direction (direction normal to the cross section illustrated in FIG. 7B). In this example, the width of trench 44 is 30 nm or less for example.

Trench 44 is filled with embedded wiring portion 45 comprising metal such as W which is disposed so as to face element portion 42. Embedded wiring portion 45 is structured as a double layer of first layer 46 provided so as to cover the inner surface of trench 44 and second layer 47 provided so as to fill the inner side of first layer 46 inside trench 44.

First layer 46 and second layer 47 are formed for example by CVD or ALD. In this example, first layer 46 contains relatively low concentration of F or Cl impurity, containing substantially no F nor Cl, and relatively high concentration of carbon C or O. In contrast, second layer 47 contains relatively high concentration of F or Cl impurity.

The manufacturing of semiconductor device 41 structured as described above follows a process flow similar to the process flow of the first embodiment. More specifically, first layer 46 is formed in a workpiece, having trench 44 formed through insulating film 43, by a first CVD process using a source such as tungsten carbonyl (W(CO)₆) which does not contain fluorine (F) nor chlorine (Cl). It is difficult to achieve sufficient coverage when (W(CO)₆) is decomposed by an ordinary thermal decomposition. Thus, sufficient amount of carrier gas such as CO is used to optimize partial pressure to achieve good coverage in the recessed pattern. The above described process deposits W in a predetermined thickness along the surface of insulating film 43 including the inner surface of trench 44 inclusive of the exposed portion of element portion 42. In this example, the thickness of the deposited W is controlled to approximately 10% of the width of trench 44 for example which may be equal to or less than for example 3 nm so that the opening portion of trench 44 is not closed.

Next, a second CVD process is carried out for forming second layer 47 using a source which contains F or Cl such as WF₆ or WCl₆ by transferring the workpiece to a different chamber or by switching the supply of gas within the same chamber. Thus, it is possible to achieve good filling of trench 44 by CVD using a source which contains F or Cl such as WF₆ or WCl₆. As a result, trench 44 is filled with a double layer of first layer 46 and second layer 47 comprising W and the upper surface of insulating film 43 is also covered with a deposit of the double layer comprising W as shown in FIG. 7A.

Then, as illustrated in FIG. 7B, unwanted portions of the double-layered stack comprising W disposed above insulating film 43 is removed by etch back, CMP, or the like to expose the surface of insulating film 43 in other words, the upper end of embedded wiring portion 45.

In the fifth embodiment described above, it is possible to obtain a low-resistance embedded wiring portion 45 provided with first layer 46 and second layer 47 comprising W. First layer 46 located in element portion 42 side of embedded wiring portion 45 contains low concentration of F or Cl impurity. Thus, it is possible to suppress damages to element portion 42 originating from the diffusion of impurities and piling of impurities at the interface of first layer 46 and element portion 42 while also inhibiting degradation of adhesion between the structures.

A description on the process for forming an adhesion layer such as a TiN layer carried out prior to W deposition for first layer 46 is not given in the fifth embodiment. However, forming the adhesion layer prior to the formation of first layer 46 will maintain the advantages obtained in a structure without an adhesion layer. If such formation of the adhesion layer is not carried out, first layer 46 may be nitridized in NH₃ atmosphere to serve as an adhesion layer. The influence of the impurity species have been discussed thus far. However, when given a choice of two types of gas sources with one containing F impurity and the other containing Cl impurity, the first layer may contain a chloride and the second layer may contain a fluoride.

### OTHER EMBODIMENTS

In the foregoing embodiments, W is used as a metal for forming a plug, wiring, and embedded wiring portion. However, molybdenum (Mo) may be used instead of W. For example, it is possible to form the plug, wiring, and embedded wiring portion by using a source of Mo carbonyl in the first layer and a source containing F or Cl such as molybdenum hexafluoride or molybdenum pentachloride in the second layer. It is possible to obtain a wiring portion having increasingly lower resistance when Mo is used since recrystallization temperature of Mo at low melting point is lower than W and thereby easily forms in large grain diameters and not prone to form fine grains. Further, it is easier to obtain good alignment of grain boundaries in a Mo film than in a W film and thereby provides good film properties. W and Mo may coexist by using different materials in the first layer and in the second layer. For example, in the first embodiment, the first layer may contain Mo and the second layer may contain W, whereas in the fifth embodiment, the first layer may contain W and the second layer may contain Mo.

Impurity species may be selected in view of relative adhesion and damage resistance. For example, diffusion of F is prone to cause formation of SiF bond, or the like. The diffusion of F is also susceptible to facilitate etching and consequently degrade adhesion, and is also prone to react with element portions and cause device degradation. Thus, F is disposed away from direct bonding sites where strong adhesion is required and from the vicinity of element portions. Since large amount of F content produces a highly-stressed film, it is useful to form the wiring portion with a combination of different gas species in view of reducing the F content as much as possible. Thus, among two types of gas sources containing F and Cl respectively, a gas source containing Cl may be used in the CVD process for forming the first layer. However, when using a chloride as the source of the first layer, it is difficult to form the first layer directly on SiO₂ film. Thus, such chloride source is used in embodiments which form an adhesion layer serving as an underlay such as a TiN layer.

The forgoing embodiments were directed to applications for filling holes serving as via holes or contact holes; however, the embodiments may be directed to applications for filling recesses other than holes such as trenches.

The foregoing embodiments formed the first layer and the second layer by CVD; however, ALD (Atomic Layer Deposition) may be used instead.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an insulating film including a recess; and
a wiring structure including at least either of tungsten and molybdenum, the wiring structure including a wiring portion provided along a surface portion of the insulating film and provided with a first layer and a second layer, a concentration of at least either of fluorine and chlorine in the second layer being greater than a concentration of either of fluorine and chlorine in the first layer, and a plug filling the recess of the insulating film and being connected to the wiring portion, the plug being continuous with and structurally integral with the second layer of the wiring portion.

2. The device according to claim 1, wherein the first layer is disposed along the surface portion of the insulating film and the second layer is disposed above and along the first layer.

3. The device according to claim 1, wherein the second layer is disposed along the surface portion of the insulating film and the first layer is disposed above and along the second layer.

4. The device according to claim 1, wherein the insulating film is provided with a rounded portion located at an opening portion of the recess.

5. The device according to claim 1, further comprising an adhesion layer disposed along a surface of the insulating film and along an inner surface of the recess.

6. The device according to claim 5, wherein the adhesion layer contains at least either of titanium and titanium nitride.

7. The device according to claim 1, wherein the first layer and the second layer of the wiring portion each comprises tungsten or molybdenum.

8. The device according to claim 1, wherein the recess of the insulating film is a trench or a hole.

9. A semiconductor device comprising:
an insulating film including a recess; and
an embedded wiring portion including at least either of tungsten and molybdenum, the embedded wiring portion provided with a first layer filled in the recess of the insulating film so as to cover an inner surface of the recess, and a second layer filing an inner side of the first layer in the recess, a concentration of at least either of fluorine and chlorine in the second layer being greater than a concentration of either of fluorine and chlorine in the first layer.

10. A method of manufacturing a semiconductor device provided with an insulating film having a recess and a wiring structure containing at least either of tungsten and molybdenum and being provided along the insulating film, the method comprising:
forming a wiring portion by depositing, a first layer by chemical vapor deposition or atomic layer deposition using a first source containing substantially no fluorine, and depositing a second layer by chemical vapor deposition or atomic layer deposition using a second source containing at least either of fluorine or chlorine and being different from the first source, the first layer and the second layer being stacked along a surface portion of the insulating film.

11. The method according to claim 10, wherein the first layer is deposited along the surface portion of the insulating film having the recess formed therein without closing an opening portion of the recess, the first source further containing substantially no chlorine, and the second layer is deposited along a surface portion of the first layer, and wherein forming the wiring portion further includes forming a plug continuous with the second layer into the recess, the wiring portion being patterned by removing unwanted portions of the first layer and the second layer formed above the surface portion of the insulating film.

12. The method according to claim 11 further comprising, after depositing the first layer and before forming the plug and depositing the second layer, forming a silicon film serving as an underlay in the recess and along the surface portion of the first layer.

13. The method according to claim 11 further comprising, before forming the wiring portion, forming an adhesion layer along the surface of the insulating film and along an inner surface of the recess.

14. The method according to claim 13, wherein the adhesion layer contains at least either of titanium and titanium nitride.

15. The method according to claim 10, wherein forming the wiring portion further includes forming an adhesion layer along the surface portion of the insulating film having the recess formed therein, the second layer being deposited along a surface portion of the adhesion layer, and wherein forming the wiring portion further includes, forming a plug continuous with the second layer into the recess, the first layer being deposited along a surface portion of the second layer, the first source further containing substantially no chlorine, the wiring portion being patterned by removing unwanted portions of the adhesion layer, the second layer, and the first layer formed above the surface portion of the insulating film.

16. The method according to claim 15, wherein forming the wiring portion further includes, after forming the plug and depositing the second layer and before depositing the first layer, forming an amorphous layer along the surface portion of the second layer.

17. The method according to claim 10, wherein the first source comprises either of tungsten carbonyl and molybdenum carbonyl.

18. The method according to claim 10, wherein the second source comprises either of tungsten hexafluoride, tungsten hexachloride, molybdenum hexafluoride, and molybdenum pentachloride.

19. The method according to claim 10, further comprising, before forming the wiring portion, forming a rounded portion at an opening portion of the recess of the insulating film.

20. The method according to claim 10, wherein the wiring portion is an embedded wiring portion formed by filling the recess, the first layer being further deposited along an inner surface of the recess, the first source further containing substantially no chlorine, the second layer being deposited along a surface portion of the first layer so as to fill the recess, and wherein forming the wiring portion includes removing unwanted portions of the first layer and the second layer formed above the surface portion of the insulating film exclusive of the first layer and the second layer formed inside the recess.
